(19) United States
(12) Patent Application Publication
(10) Pub. No.: US 2007/0158180 A1
(43) Pub. Date: Jul. 12, 2007

(54) Magnetron sputtering method and magnetron sputtering apparatus

(75) Inventors: Atsushi Ota, Chiba (JP); Shinichiro Taguchi, Chiba (JP); Isao Sugiura, Chiba (JP); Noriaki Tani, Chiba (JP); Makoto Arai, Chiba (JP); Junya Kiyota, Chiba (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: ULVAC, Inc., Chigasaki-shi (JP)

(21) Appl. No.: 11/606,363

(22) Filed: Nov. 30, 2006

Related U.S. Application Data
(63) Continuation of application No. PCT/JP05/10385, filed on Jun. 7, 2005.

(30) Foreign Application Priority Data
Jun. 7, 2004 (JP) 2004-168653

(51) Int. Cl. C23C 14/32; C23C 14/00

(52) U.S. Cl. 204/192.1; 204/298.16

(57) ABSTRACT

The present invention provides a magnetron sputtering method and a magnetron sputtering apparatus that can significantly reduce a non-erosion region causing an abnormal electrical discharge on a surface of a target and deposition of target materials. A plurality of targets 8A, 8B, 8C and 8D are disposed in a vacuum atmosphere while being electrically independent to each other; and sputtering is performed by generating magnetron discharge in the vicinity of the targets 8A, 8B, 8C and 8D. During the sputtering, voltages having a phase difference of 180 degrees are alternately applied to the adjacent targets 8A, 8B, 8C and 8D at a predetermined timing.

This is a Continuation of International Application No. PCT/JP2005/010385 filed Jun. 7, 2005. The entire disclosure of the prior application is hereby incorporated by reference herein in its entirety.

### BACKGROUND OF THE INVENTION

1. Field of the Invention

The present invention generally relates to magnetron sputtering methods and magnetron sputtering apparatuses, and more particularly, the present invention relates to magnetron sputtering methods and magnetron sputtering apparatuses having a plurality of targets in a vacuum chamber.

2. Discussion of the relevant art

Conventionally, a magnetron sputtering apparatus shown in FIG. 6 is known as a type of magnetron sputtering apparatus.

As shown in FIG. 6, a magnetron sputtering apparatus 101 has a vacuum chamber 102 that is connected to a prescribed evacuation system 103 and a prescribed gas introduction pipe 104, and a substrate 106, on which films are to be formed, is disposed in an upper portion inside the vacuum chamber 102.

In a lower portion inside the vacuum chamber 102, a plurality of targets 107 are disposed that respectively have a magnetic circuit forming member 105. Each target 107 is configured such that a predetermined voltage is applied to the target 107 from a power supply 109 via a backing plate 108.

Then, a shield 110 that is set to a ground potential is disposed between the targets 107 in order to stably generate plasma on each of the targets 107 to form a uniform film on the substrate 106.

### SUMMARY OF THE INVENTION

However, in such a conventional system or process, plasma is absorbed by the shield 110 disposed between the targets 107 during film formation so that a non-erosion region that has not been eroded remains in a region located in the vicinity of the shield 110 of each target 107.

The presence of this non-erosion region causes an abnormal electrical discharge on the surface of the target 107, or invites deterioration of the film quality by deposition of the target materials in the non-erosion region.

The present invention was achieved to solve such problems of the conventional system or process, and the present invention is directed to magnetron sputtering methods and magnetron sputtering apparatuses that can significantly reduce the non-erosion region so as to prevent an abnormal electrical discharge caused by the non-erosion region present on the surface of the target, and deposition of target materials that causes deterioration of the film quality.

In order to solve the above-described problems, the present invention provides a magnetron sputtering method comprises performing sputtering by generating magnetron discharges in the vicinity of a plurality of targets, the targets being disposed close to each other in order to be directly opposed to the adjacent targets and each of the targets is electrically independent in a vacuum atmosphere, and applying voltages having a phase difference of 180 degrees to the adjacent targets at a prescribed timing during the sputtering.

In the above-described magnetron sputtering method, the voltages having a phase difference of 180 degrees can be periodically and alternately applied to the adjacent targets.

In the above-described magnetron sputtering method, the voltages applied to the adjacent targets may be pulsed DC voltages.

In the above-described magnetron sputtering method, frequencies of the voltages applied to the adjacent targets may be equal.

In the above-described magnetron sputtering method, voltages applied to the adjacent targets are always exclusive to each other.

The present invention provides a magnetron sputtering apparatus including a plurality of targets electrically independent to each other disposed in a vacuum chamber, wherein adjacent targets are disposed close to each other so as to directly oppose to each other, and a voltage supply portion is further provided that has a power supply capable of applying to each target voltage having a phase difference of 180 degrees respectively at a predetermined timing.

In the above-described magnetron sputtering apparatus, a space between the adjacent targets may be set to a distance such that an abnormal electrical discharge does not occur between the adjacent targets; and also, plasma is not generated between the adjacent targets.

In the method of the present invention, by applying voltages having a phase difference of 180 degrees to the adjacent targets that are disposed close to each other at a prescribed timing during sputtering, it becomes possible to stably generate a uniform plasma on each target even in a state in which a shield is not provided between the targets.

As a result, according to the present invention, the non-erosion region can be significantly reduced; and consequently, it is possible to prevent an abnormal electrical discharge on the surface of the target, as well as to prevent deposition of target materials in the non-erosion region as much as possible.

In addition, with the apparatus of the present invention, the above-described method of the present invention can be easily performed with good efficiency.

According to the present invention, it is possible to stably generate uniform plasma on each target even in a state in which a shield is not provided between the targets. Consequently, it is possible to prevent an abnormal electrical discharge on the surface of the target, as well as to prevent deposition of target materials in the non-erosion region as much as possible.

### BRIEF DESCRIPTION OF THE DRAWINGS

FIG. 1 is a cross-sectional view showing a configuration of a magnetron sputtering apparatus according to an embodiment of the present invention.

FIG. 2 is a timing chart showing an example of waveforms of voltages applied to targets of the present invention.

FIG. 3 shows timing charts showing the relationships between frequencies and waveforms of the voltages applied to the targets.

FIGS. 4(a) and 4(b) are timing charts showing another example of waveforms of voltages applied to the targets.

FIG. 5(a) is an explanatory diagram showing a state of targets of a comparative example.

FIG. 5(b) is an explanatory diagram showing a state of targets of a working example.

FIG. 6 is a cross-sectional view showing a configuration of a magnetron sputtering apparatus according to conventional techniques.

### DETAILED DESCRIPTION OF THE INVENTION

A preferred embodiment of the present invention is described below in detail with reference to accompanying drawings.

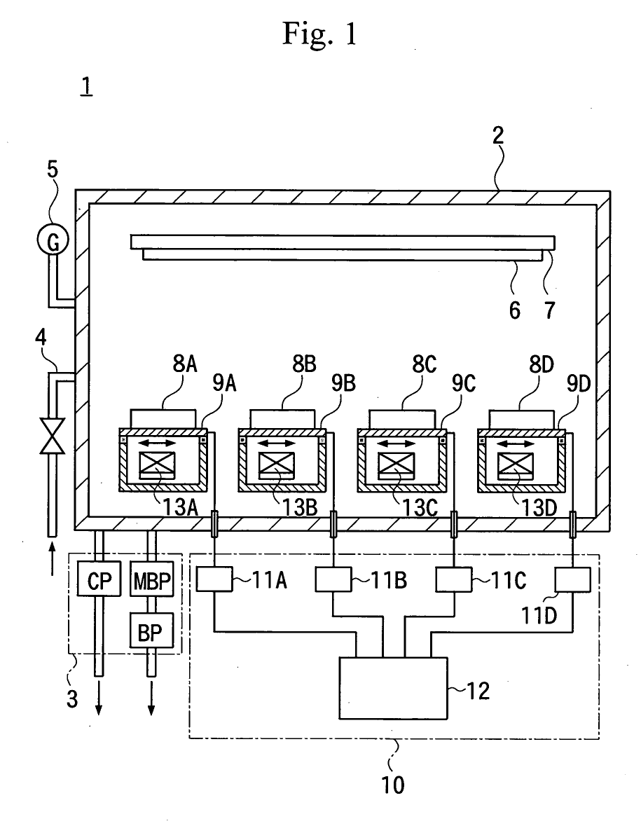

FIG. 1 is a cross-sectional view showing a configuration of a magnetron sputtering apparatus according to an embodiment of the present invention.

As shown in FIG. 1, a magnetron sputtering apparatus 1 of the present embodiment has a vacuum chamber 2 to which a prescribed evacuation system 3 and a prescribed gas introduction pipe 4 are connected and to which a vacuum gauge 5 is also attached.

In an upper portion inside the vacuum chamber 2, a substrate 6 that is connected to a power supply (not shown) is disposed while being held by a substrate holder 7.

In the present invention, while it is possible to fix the substrate 6 at a prescribed position in the vacuum chamber 2, with a view to securing a uniform film thickness, it is preferable to adopt a configuration in which the substrate 6 is moved by way of swaying, rotation or shifting.

In a lower portion inside the vacuum chamber 2, a plurality of targets 8 (in the present embodiment, 8A, 8B, 8C and 8D) are respectively placed on backing plates 9A, 9B, 9C and 9D, being electrically independent of one another.

In the present invention, the number of targets 8 is not particularly limited. However, with a view to achieving more stable electrical discharge, it is preferable to provide an even number of targets 8.

In the present embodiment, the targets 8A, 8B, 8C and 8D are formed in, for example, a rectangular shape, and are provided at the same height. With a view to securing a uniform film thickness (film quality), the targets 8A, 8B, 8C and 8D are disposed close to each other such that side face portions in the longitudinal direction of the respective adjacent targets 8A and 8B, 8B and 8C, and 8C and 8D directly opposed to each other.

In this case, with a view to securing a uniform film thickness (film quality), it is preferable to adopt a configuration in which a region for disposing the targets 8A, 8B, 8C and 8D is larger than the size of the substrate 6.

In the present invention, a spacing between the adjacent targets 8A and 8B, 8B and 8C, and 8C and 8D is not limited to a particular distance. However, it is preferable to set the spacing to a distance at which an abnormal electrical discharge (arc discharge) does not occur between the adjacent targets, and further plasma is not generated between the adjacent targets 8A and 8B, 8B and 8C, and 8C and 8D based on Paschen's law.

In the present embodiment, it is confirmed by this invention that when the spacing between the adjacent targets 8A and 8B, 8B and 8C, and 8C and 8D is less than 1 mm, an abnormal electrical discharge (arc discharge) occurs between the adjacent targets, whereas plasma is generated when the spacing exceeds 60 mm (pressure: 0.3 Pa, supplied power: 10 W/cm²).

Also, taking a drawback that a film adheres to the side face portion or the like in the longitudinal direction of the targets 8A to 8D into account, it is more preferable to set the spacing to 1 mm or more and 3 mm or less.

On the other hand, a voltage supply portion 10 for applying a prescribed voltage to the targets 8A, 8B, 8C and 8D is provided on the outside of the vacuum chamber 2.

The voltage supply portion 10 of the present embodiment has power supplies 11A, 11B, 11C and 11D that respectively correspond to the targets 8A, 8B, 8C and 8D. These power supplies 11A, 11B, 11C and 11D are connected to a voltage control portion 12 such that the magnitude and timing of output voltages are controlled; and thus, prescribed voltages described below are applied respectively to the targets 8A, 8B, 8C and 8D via the backing plates 9A, 9B, 9C and 9D.

Below the backing plates 9A, 9B, 9C and 9D, namely, on the side of the backing plates 9A, 9B, 9C and 9D opposite to the targets 8A, 8B, 8C and 8D, magnetic circuit forming members 13A, 13B, 13C and 13D are provided including a, for example, permanent magnet.

In the present invention, although it is possible to fix the magnetic circuit forming members 13A, 13B, 13C and 13D at prescribed positions, with a view to achieving uniformity in formed magnetic circuits, it is preferable to adopt, for example, a configuration in which the magnetic circuit forming members 13A, 13B, 13C and 13D reciprocally move in a horizontal direction.

It should be noted that it is preferable to configure the magnetic circuit such that the leakage magnetic field produced on the surface of each of the targets 8A, 8B, 8C and 8D is such that the horizontal magnetic field is 100 to 2000 G at the position with a vertical magnetic field of 0.

A preferred embodiment of a magnetron sputtering method according to the present invention is described below.

In the present embodiment, when sputtering is performed under a prescribed pressure after a sputtering gas is introduced to the inside of the vacuum chamber 2, voltages having a phase difference of 180 degrees are applied at a prescribed timing to the adjacent targets 8A and 8B, 8B and 8C, and 8C and 8D.

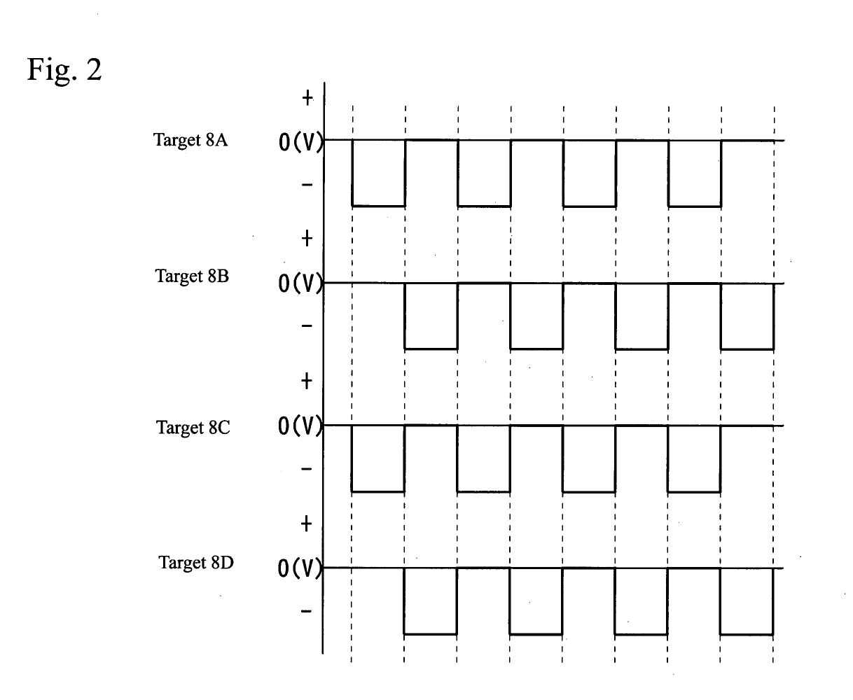

FIG. 2 is a timing chart showing an example of waveforms of voltages applied to the targets of the present invention.

As shown in FIG. 2, in this example, voltages having a phase difference of 180 degrees as described below, for example, are periodically and alternately applied to the adjacent targets 8A and 8B, 8B and 8C, and 8C and 8D.

More particularly, in this example, pulsed DC voltages are applied to the targets 8A to 8D.

In this case, in view of reliably generating plasma on the targets 8A to 8D, it is preferable that the voltages applied to the adjacent targets 8A and 8B, 8B and 8C, and 8C and 8D have waveforms that are exclusive to each other that include no period in which the voltages applied to the adjacent targets are at the same potential; i.e., waveforms that do not overlap each other.

In the present invention, it is preferable that the frequency of the voltages applied to the targets 8A to 8D is as low as possible in a range in which charged electrical charges escape (specifically, e.g., 1 Hz or more).

The upper limit of the frequency of the voltages applied to the targets 8A to 8D is set as described below.

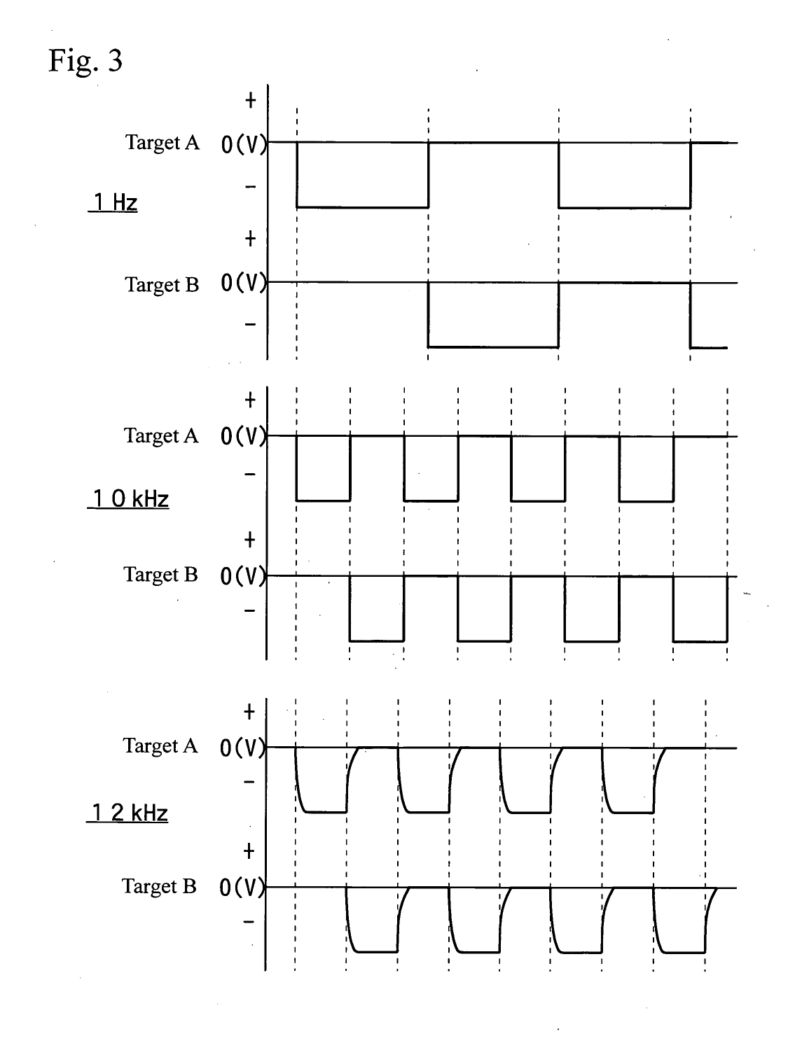

FIG. 3 shows timing charts showing the relationship between the frequencies and the waveforms of the voltages applied to the targets.

A case is described in which the above-described pulsed DC voltages are applied to adjacent targets A and B that have the configuration described above. As shown in FIG. 3, it is confirmed in this invention that up to 10 kHz, an effect of the capacitances of the targets A and B and their circuits is small; and therefore, the waveform (rectangular shape) is not deformed. As a result, by applying voltages exclusively to the adjacent targets A and B, plasma can be reliably generated on the targets A and B.

On the other hand, it is confirmed in the present invention that when the frequency of the applied voltage exceeds 10 kHz (12 kHz in FIG. 3), an effect of the capacitance of the target A and B and their circuits cannot be neglected; and therefore, the waveform is deformed so as to be similar to a sine wave. As a result, in the waveforms of the voltages applied to the adjacent targets A and B, a period appears in which the voltages have the same potential; and thus, it becomes impossible to reliably generate plasma on the targets A and B as described above.

Accordingly, in the present embodiment, the frequency of the voltages applied to the targets 8A to 8D is preferably 1 Hz to 10 kHz.

In the present invention, although the adjacent targets 8A to 8D may be applied with the voltages of different frequencies, in view of securing a uniform film thickness, it is preferable to apply voltages of the same frequency to the adjacent targets 8A to 8D.

The magnitude of the voltages (electric power) applied to the adjacent targets 8A to 8D is not particularly limited. However, in view of securing a uniform film thickness, it is preferable to apply voltages of the same magnitude to the adjacent targets 8A to 8D.

In this case, in view of stably generating plasma on the targets 8A to 8D, it is preferable to set the maximum value in the positive (+) direction of the applied voltage to be equal to the ground potential.

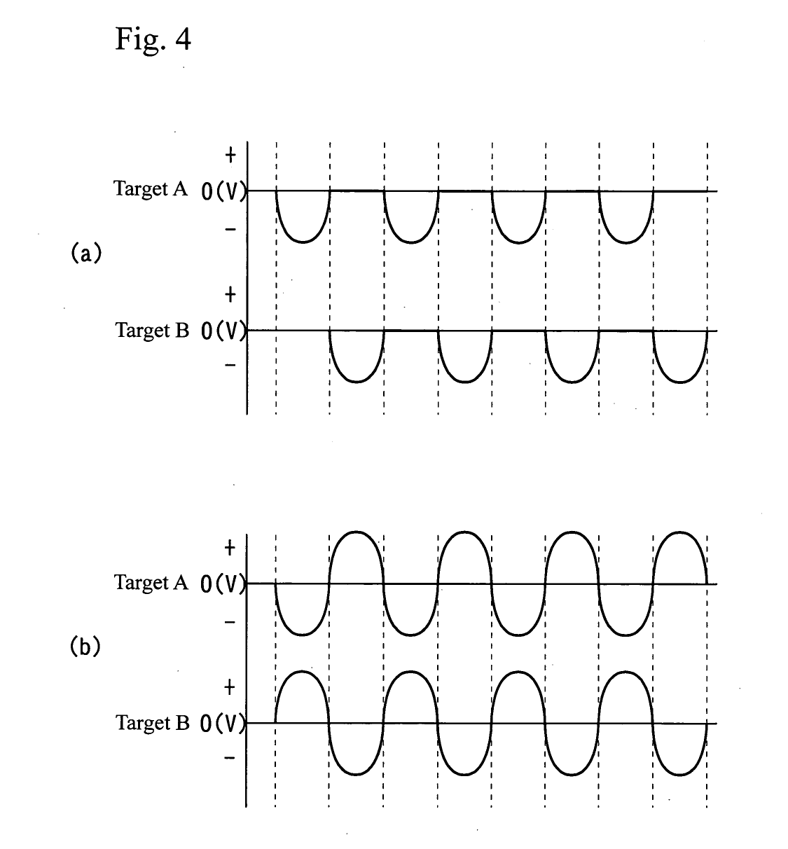

FIGS. 4(a) and 4(b) are timing charts showing another example of waveforms of voltages applied to the targets.

As shown in FIGS. 4(a) and 4(b), in the present invention, instead of the above-described pulsed DC voltage, AC (alternation) voltages having a phase difference of 180 degrees can be periodically and alternately applied to the adjacent targets.

In this example as well, in view of reliably generating plasma on the targets 8A to 8D, it is preferable that the voltages applied to the adjacent targets 8A and 8B, 8B and 8C, and 8C and 8D have waveforms exclusive to each other that include no period in which the voltages applied to the adjacent targets are at the same potential; i.e., waveforms that do not mutually overlap.

Also, it is preferable that the frequency of the voltages applied to the targets 8A to 8D is as low as possible in a range in which charged electrical charges escape (specifically, e.g., 1 Hz or more).

On the other hand, with respect to the upper limit of the frequency of the voltages applied to the target 8A to 8D, it is confirmed by the present invention that the extent of deformation of the waveform due to an increase of the frequency is small compared with the case of the above-described pulsed DC voltage; and thus, it is possible to apply a voltage having a frequency of up to about 60 kHz.

Accordingly, in this example, the frequency of the voltages applied to the targets 8A to 8D is preferably 1 Hz to 40 kHz.

According to the present embodiment described above, by applying voltages having a phase difference of 180 degrees to the adjacent targets 8A and 8B, 8B and 8C, and 8C and 8D that are disposed close to each other during sputtering, it is possible to reliably generate uniform plasma on the targets 8A to 8D even in a state in which shields are not provided between the targets 8A to 8D. As a result, the non-erosion region in the targets 8A to 8D can be significantly reduced; and therefore, it is possible to prevent an abnormal electrical discharge on the surface of the targets 8A to 8D, as well as to prevent deposition of target materials in the non-erosion region as much as possible.

Also, with the magnetron sputtering apparatus 1 of the present embodiment, the above-described method of the present invention can be easily performed with good efficiency.

The present invention can be applied to an unprescribed number of various types of targets; and there is no restriction to the type of a sputtering gas that can be introduced.

### EXAMPLES

A working example of the present invention is described below.

### Working Example

The magnetron sputtering apparatus shown in FIG. 1 is used and six sheets of targets obtained by adding 10 wt % of SnO₂ to In₂O₃ are disposed in the vacuum chamber.

Then, a sputtering gas including Ar and O₂ was introduced to the inside of the vacuum chamber. Under a pressure of 0.7 Pa, voltages that have pulsed rectangular waves with the opposite phases (frequency: 50 Hz, supplied power: 6.0 kW) as shown in FIG. 2 are applied to the targets to perform sputtering.

### Comparative Example

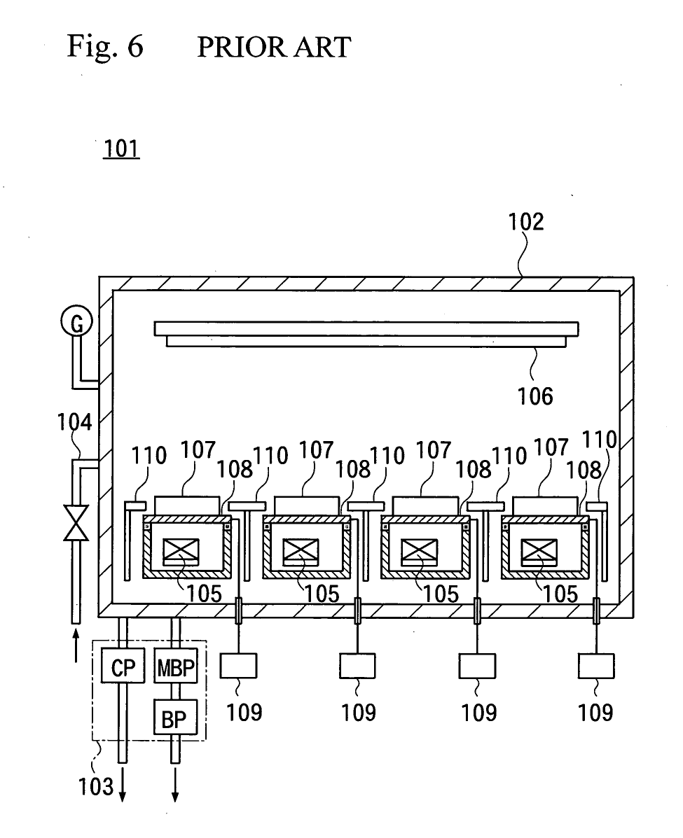

Sputtering is performed under the same process conditions as those of the working example, using the magnetron sputtering apparatus of the conventional techniques shown in FIG. 6.

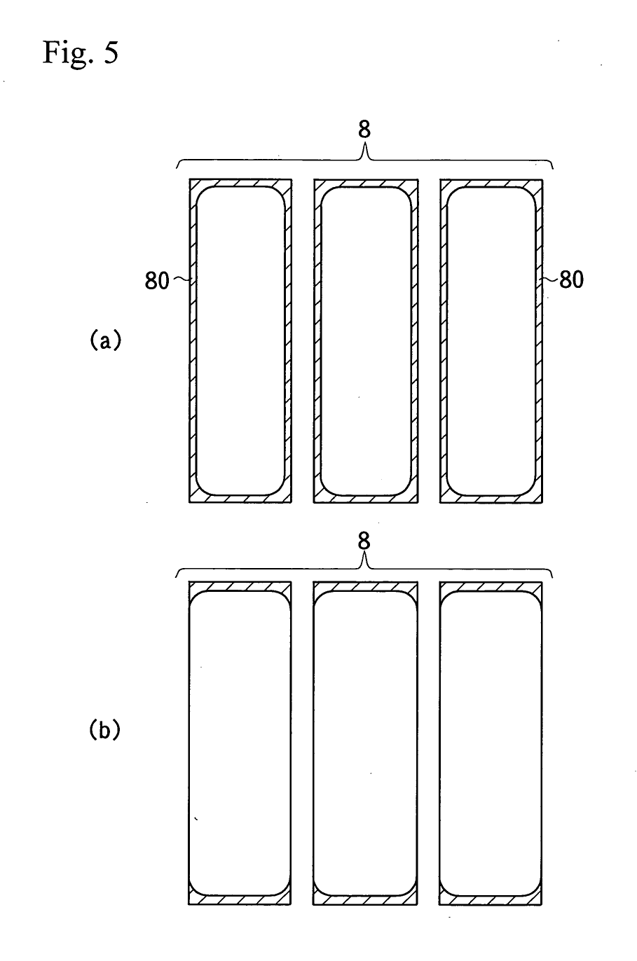

While a non-erosion region 80 with a width of approximately 10 mm is present on the rim portion of the target 8 in the comparative example as shown FIG. 5(a), and almost no non-erosion region is present in the rim portion of the target 8 in the working example as shown in FIG. 5(b).

What is claimed is:

1. A magnetron sputtering method, comprising;
performing sputtering by generating a magnetron discharge in the vicinity of a plurality of targets, the targets being disposed in close each other in order to be directly opposed to the adjacent targets, wherein each of the targets is electrically independent in a vacuum atmosphere; and
applying voltages having a phase difference of 180 degrees to the adjacent targets at a prescribed timing during the sputtering.

2. The magnetron sputtering method according to claim 1, wherein the voltages having a phase difference of 180 degrees are periodically and alternately applied to the adjacent targets.

3. The magnetron sputtering method according to claim 1, wherein the voltages applied to the adjacent targets are pulsed DC voltages.

4. The magnetron sputtering method according to claim 1, wherein frequencies of the voltages applied to the adjacent targets are equal.

5. The magnetron sputtering method according to claim 1, wherein voltages applied to the adjacent targets are always exclusive to each other.

6. A magnetron sputtering apparatus, comprising:
a plurality of targets electrically independent to each other disposed in a vacuum chamber, wherein the targets are disposed close to each other in order to be directly opposed to the adjacent targets; and
a voltage supply member having a power supply capable of applying voltage having a phase difference of 180 degrees to each target respectively at a predetermined timing.

7. The magnetron sputtering apparatus according to claim 6, wherein a space between the adjacent targets is set to a distance that an abnormal electrical discharge does not occur between the adjacent targets, and also plasma is not generated between the adjacent targets.
